(19) United States
(12) Patent Application Publication
(10) Pub. No.: US 2003/0222341 A1
(43) Pub. Date: Dec. 4, 2003

(54) Systems and methods for cooling microelectronic devices using oscillatory devices

(76) Inventors: Bruce J. Oberhardt, Raleigh, NC (US); Jason M. Zara, Washington, DC (US); Stephen W. Smith, Durham, NC (US)

Correspondence Address: MYERS BIGEL SIBLEY & SAJOVEC, PO BOX 37428, RALEIGH, NC, 27627, US

(21) Appl. No.: 10/396,133

(22) Filed: Mar. 25, 2003

Related U.S. Application Data
(60) Provisional application No. 60/369,306, filed on Apr. 1, 2002.

(51) Int. Cl. H01L 21/48; H01L 23/10

(52) U.S. Cl. 257/706; 438/122; 257/723; 438/107

(57) ABSTRACT

Microelectromechanical (MEMS) oscillatory devices are placed adjacent a face of a microelectronic substrate and configured to oscillate to dissipate at least some heat that is generated by the microelectronic substrate during operation thereof. The MEMS oscillatory devices can be configured to oscillate to disrupt the thermal boundary layer that is formed adjacent the face of the microelectronic substrate, which may limit heat dissipation therefrom. MEMS oscillatory devices may be far less susceptible to wear and breakdown than MEMS rotary devices, such as fans.

### CROSS-REFERENCE TO PROVISIONAL APPLICATION

This application claims the benefit of provisional Application No. 60/369,306, filed Apr. 1, 2002, entitled Methods and Apparatuses for Cooling Microchips, assigned to the assignee of the present application, the disclosure of which is hereby incorporated herein by reference in its entirety as if set forth fully herein.

### FIELD OF THE INVENTION

This invention relates to microelectronic devices and operating methods therefor, and more particularly to systems and methods for cooling microelectronic devices.

### BACKGROUND OF THE INVENTION

Microelectronic devices are widely used in consumer and commercial applications. As the integration densities and operating frequencies of microelectronic devices continue to increase, heat dissipation may become an increasingly challenging problem. For example, present-day microprocessor integrated circuits may generate from several to tens of watts during operations. Moreover, future microprocessors are projected to produce over 100 watts. Other microelectronic devices such as lasers and power devices may generate large amounts of heat during operations.

Microelectronic device packaging systems have been designed to dissipate the heat produced by microelectronic devices. For example, mainframe computer systems have long used complex thermal conduction systems to dissipate heat. Less expensive electronic products such as personal computers have also used heat sinks on individual integrated circuits and/or fans in the personal computer housing to dissipate heat. It is also known to attach a fan directly to an integrated circuit. Moreover, it has recently been proposed to provide an array of microfans on an integrated circuit substrate. In particular, the Office of News Services at the University of Colorado at Boulder has indicated that faculty and student researchers in the Department of Mechanical Engineering have built a microfan that consists of eight blades, each of about half-millimeter long, which are connected to a tiny motor with silicon strips that act as hinges. The fan is so small that an array of almost 300 such devices could be assembled in a square inch of space. See the University of Colorado Boulder News, Press Release, Feb. 27, 2001. The New York Times also reported on this work on Feb. 15, 2001 and indicated that, to supply enough air to cool the powerful chips of the future, arrays of the fans will have to spin very fast. See Eisenberg, “What's Next”, New York Times, Feb. 15, 2001. See also, Kladitis et al., Solder Self-Assembled Micro Axial Flow Fan Driven by a Scratch Drive Actuator Rotary Motor, Proc. 14th IEEE International Micro Electro Mechanical Systems Conference (MEMS 2001), Interlaken, Switzerland, Jan. 21-25, 2001, pp. 598-601.

### SUMMARY OF THE INVENTION

Microelectronic devices according to some embodiments of the present invention comprise a microelectronic substrate including a face and a plurality of microelectromechanical (MEMS) oscillatory devices adjacent the face that are configured to oscillate to dissipate at least some heat that is generated by the microelectronic substrate during operation thereof. The plurality of microelectromechanical oscillatory devices may be configured to oscillate in a direction that is parallel to the face, in a direction that is orthogonal to the face and/or in a direction that is oblique to the face. The microelectromechanical oscillatory devices may be arranged on the face in a regular array and/or in a random array.

Some embodiments of the present invention may stem from the recognition that when a microelectronic substrate generates heat during operation thereof and at least some of the heat is removed by a fluid flow adjacent the face, the fluid flow defines a thermal boundary layer. Heat dissipation through the thermal boundary layer may take place primarily by conduction. Embodiments of the present invention can provide a plurality of microelectromechanical oscillatory devices that are configured to oscillate to disrupt the thermal boundary layer so that at least some heat may be removed via convection. Rotary microelectromechanical devices such as fans, which are susceptible to friction and wear, need not be used. Rather, microelectromechanical oscillatory devices, which may be far less susceptible to wear and breakdown may be used to oscillate to disrupt the thermal boundary layer. In some embodiments, the microelectromechanical oscillatory devices are configured to extend adjacent and/or at least partially into the thermal boundary layer and, in other embodiments, the plurality of microelectromechanical oscillatory devices are located within the thermal boundary layer.

In some embodiments of the present invention, the plurality of microelectromechanical oscillatory devices comprise a plurality of blades and a plurality of microelectromechanical actuators, a respective one of which is configured to oscillate a respective one of the blades. In some embodiments, the blades extend along the face and the microelectromechanical actuators are configured to oscillate the blades in a direction that is parallel to the face. In other embodiments, the blades extend orthogonal and/or oblique to the face and the microelectromechanical actuators are configured to oscillate the blades in the direction that is parallel to the face. In yet other embodiments, the microelectromechanical actuators comprise conventional microelectromechanical integrated force arrays.

In other embodiments according to the present invention, the microelectromechanical oscillatory devices comprise a plurality of flaps and a plurality of microelectromechanical actuators, a respective one of which is configured to oscillate a respective one of the flaps. In some embodiments, the flaps extend along the face and the microelectromechanical actuators are configured to oscillate the plurality of blades in the direction that is orthogonal to the face. In other embodiments, the microelectromechanical oscillators comprise a plurality of electrostatically actuated flaps. In other embodiments, the plurality of microelectromechanical flaps each comprises a strip including a fixed end and a free end that is opposite the fixed end. In some embodiments, the strip is configured to pivot about the fixed end in an oscillatory manner. In other embodiments, the strip is configured to bend in an oscillatory manner. In still other embodiments, the strip is configured to uncoil and recoil in an oscillatory manner.

In any of the above embodiments, the plurality of microelectromechanical oscillatory devices may be configured to oscillate in response to electrostatic, magnetic, piezoelectric, thermal, and/or other actuation forces. Also, in any of the above-described embodiments, the plurality of microelectromechanical oscillatory devices may be configured to oscillate at the same frequency and/or different frequencies. Also, any of the above-described embodiments may be used in a liquid and/or a gas ambient. Any of the above-described embodiments may be used adjacent or on multiple faces of the substrate.

Finally, although the above-described embodiments have been described in connection with microelectronic structures, analogous methods of dissipating heat from a microelectronic substrate by providing a plurality of microelectromechanical oscillatory devices and/or by disrupting the thermal boundary layer also may be provided. Analogous structures and methods for dissipating heat from a heat-producing component other than a microelectronic substrate also may be provided. Analogous structures and methods that use electromechanical devices and/or electromechanical oscillatory devices also may be provided. Cooling devices and methods that are configured to be coupled to microelectronic substrates and/or other heat-producing components also may be provided.

### BRIEF DESCRIPTION OF THE DRAWINGS

FIGS. 1A-1B are a side cross-sectional and a top plan view, respectively, of heat producing components such as microelectronic devices according to some embodiments of the present invention.

FIG. 1C is a side cross-sectional view of heat producing components such as microelectronic devices according to other embodiments of the present invention.

FIG. 2 is a side cross-sectional view of heat producing components such as microelectronic devices according to still other embodiments of the present invention.

FIG. 3 is a top plan view of heat producing components such as microelectronic devices according to yet other embodiments of the present invention.

FIGS. 4-8 are side cross-sectional views of heat producing components such as microelectronic devices according to still other embodiments of the present invention.

FIGS. 9A-9B and 10A-10B are top plan and side cross-sectional views, respectively, of other heat producing components such as microelectronic devices according to other embodiments of the present invention, in unactuated and actuated positions, respectively.

FIG. 11 is a side cross-sectional view of heat producing components such as microelectronic devices according to other embodiments of the present invention.

FIG. 12 is a top plan view of heat producing components such as microelectronic devices according to still other embodiments of the present invention.

FIGS. 13-14 are side cross-sectional views of electronic equipment including heat producing components such as microelectronic devices according to other embodiments of the present invention.

FIGS. 15A-15B are front and side views, respectively, of microelectromechanical oscillatory devices according to some embodiments of the present invention.

FIGS. 16A-16D are a top view, a top view, a front view and a side view, respectively, of microelectromechanical oscillatory devices according to still other embodiments of the present invention.

FIGS. 17A-17C are top plan views of microelectromechanical oscillatory devices during operation according to some embodiments of the present invention.

FIG. 18 schematically illustrates an experimental setup to measure heat dissipation according to some embodiments of the present invention.

FIG. 19 graphically illustrates measured temperatures from the setup of FIG. 18.

FIG. 20 schematically illustrates another experimental setup to measure heat dissipation according to other embodiments of the present invention.

### DETAILED DESCRIPTION

The present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. Like numbers refer to like elements throughout.

It will be understood that when an element such as a layer, region or substrate is referred to as being “on” another element, it can be directly on the other element or intervening elements may also be present. It will be understood that if part of an element, such as a surface of a conductive line, is referred to as “outer,” it is closer to the outside of the integrated circuit than other parts of the element. Furthermore, relative terms such as “beneath” may be used herein to describe a relationship of one layer or region to another layer or region relative to a substrate or base layer as illustrated in the figures. It will be understood that these terms are intended to encompass different orientations of the device in addition to the orientation depicted in the figures. Finally, the term “directly” means that there are no intervening elements.

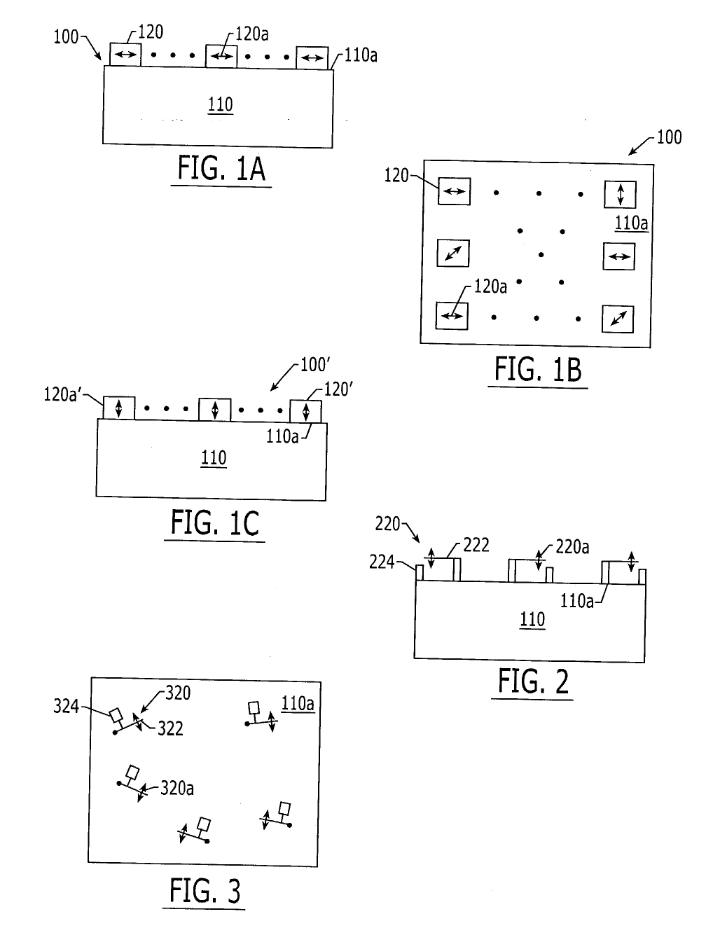

FIG. 1A is a side cross-sectional view and FIG. 1B is a top plan view of heat producing components such as microelectronic devices according to some embodiments of the present invention. As shown in FIG. 1, these heat producing components such as microelectronic devices 100 include a microelectronic substrate 110 including a face 110a. A plurality of microelectromechanical (MEMS) oscillatory devices 120 are adjacent the face 110a. As shown in embodiments of FIGS. 1A and 1B, these microelectromechanical oscillatory devices 120 are directly on the face 110a. By oscillatory, it is meant that the devices are configured to provide back and forth motion along a path, as opposed to rotary motion.

Still referring to FIGS. 1A and 1B, the microelectronic substrate 110 may be any conventional microelectronic substrate that is fabricated from elemental semiconductors such as silicon, compound semiconductors such as gallium arsenide and/or other non-semiconductor microelectronic substrates, and may include one or more conductive, semiconductive, insulating, mounting or other intermediary layers thereon. A conventional encapsulating material also may be provided thereon. Accordingly, embodiments of the invention include bare substrates, often referred to as dies, and packaged substrates, often referred as chips. The microelectronic substrate includes one or more electronic (such as discrete or integrated transistors or thyristors), electro-optical (such as a laser or light emitting diode) and/or other device that generates heat during operation thereof. The face 110a may be defined by an outer surface of the substrate, including an outer surface of any layers on the substrate or of any elements attached to the substrate.

Still continuing with the description of FIGS. 1A and 1B, the MEMS oscillatory devices 120 are of a microelectronic scale, and may be fabricated using conventional microelectronic processes such as deposition, etching, plating and/or the like. The design and fabrication of MEMS oscillatory devices are well known to those having skill in the art. Moreover, many different embodiments of MEMS oscillatory devices may be used, as will be described below.

In embodiments shown in FIGS. 1A and 1B, the MEMS oscillatory devices 120 are configured to oscillate in a direction, shown by arrows 120a, that is parallel to the face 110a. In contrast, FIG. 1C illustrates other embodiments of the present invention wherein a microelectronic device 100′ includes a plurality of MEMS oscillatory devices 120′ that are configured to oscillate in a direction that is orthogonal to the face 110a, as shown by the arrows 120a′. It will also be understood that obliquely oscillating devices also may be provided.

Referring again to FIGS. 1A-1C, in some embodiments of the present invention, the MEMS oscillatory devices are arranged on the face in a regular array, for example in an array of equally spaced apart rows and columns. However, in other embodiments of the present invention, the MEMS oscillatory devices 120, 120′ are arranged on the face in a random array, i.e., in an array of MEMS oscillatory devices that are not equally spaced apart. Moreover, in some embodiments, the MEMS oscillatory devices may all oscillate in the same direction as shown, for example, in FIGS. 1A and 1C. In contrast, in other embodiments of the present invention, as shown in FIG. 1B, the MEMS oscillatory devices may oscillate in different directions which may also be arranged in a random (non-repeating) manner. Thus, the locations and/or the directions of oscillation of the MEMS oscillatory devices may be equal, patterned and/or random relative to the face 100a, so that any spacing and/or direction is envisioned.

FIG. 2 is a side cross-sectional view of heat producing components such as microelectronic devices according to other embodiments of the invention. As shown in these embodiments, the MEMS oscillatory devices 220 comprise a plurality of flaps 222 and a plurality of MEMS actuators 224, a respective one of which is configured to oscillate a respective one of the flaps 222. As shown in FIG. 2, the plurality of flaps 222 extend along the face 110a, and the plurality of microelectromechanical actuators 224 are configured to oscillate the plurality of flaps in a direction 220a that is orthogonal to the face 110c. The size and position of the actuators 224 are indicated schematically and may vary depending on the particular actuation mechanism. It also will be understood that in any embodiment of the present invention, the structure of the flaps and actuators may be at least partially combined into an integrated structure.

FIG. 3 is a top plan view of heat producing components such as microelectronic devices according to still other embodiments of the present invention. In these embodiments, the plurality of microelectromechanical oscillatory devices 320 comprise a plurality of blades 322 and a plurality of microelectromechanical actuators 324, a respective one of which is configured to oscillate a respective one of the blades 322. As shown in FIG. 3, in some embodiments, the blades 322 extend along the face 110a and the MEMS actuators 324 are configured to oscillate the blades in a direction 320a that is parallel to the face 110a. As shown in FIG. 3, the blades 322 may oscillate in non-uniform directions 320a that are parallel to the face 110a. In other embodiments, all the blades 322 may oscillate in a same direction that is parallel to the face 110a. It will also be understood that in any embodiments of the present invention, the blades and actuators may be at least partially combined into an integrated structure. Combinations of embodiments of FIGS. 2 and 3 also may be provided. It will also be understood that any of the embodiments of the invention described herein may be used adjacent or on multiple faces of a substrate.

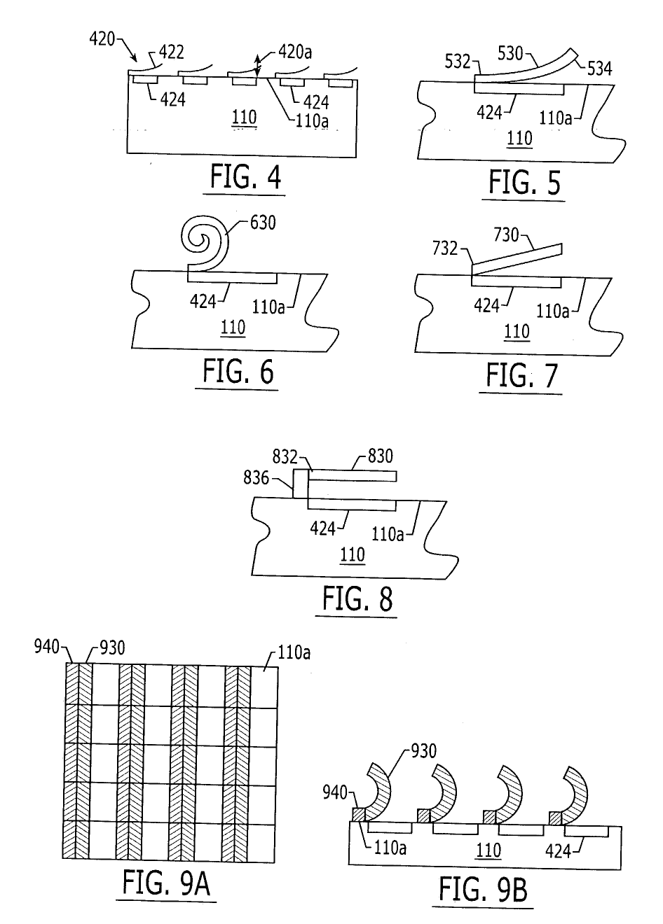

It will be understood that many types of conventional MEMS actuators may be used in embodiments of the present invention. The MEMS actuators may be actuated by electrostatic, magnetic, piezoelectric, thermal and/or other conventional MEMS actuation forces. Specific MEMS actuators that may be particularly useful with embodiments of the present invention will now be described in connections with FIGS. 4-11. However, the invention shall not be construed as limited to these embodiments.

In particular, referring to FIGS. 4-8, various embodiments of MEMS oscillatory devices that employ flaps will now be described. In particular, FIG. 4 illustrates a microelectronic substrate 110 having a plurality of flaps 422 that extend along the face 110 and a plurality of MEMS actuators 424 that are configured to oscillate the plurality of flaps in a direction that is orthogonal to the face, as indicated by 420a. As shown in FIG. 4, the MEMS actuators comprise electrostatically actuated flaps. However, other types of actuation also may be provided including, for example, bimorph flaps that are actuated thermally. Shape memory alloy devices also may be used. Other thermally actuated actuators also may be used such as thermal arched beam actuators as described, for example, in U.S. Pat. No. 5,909,078 to Wood et al. and/or thermoelectric actuators as described, for example, in Humbeeck, Non-Medical Applications of shape Memory Alloys, Materials Science and Engineering A, Vol. 273-275, Dec. 15, 199, pp. 134-148.

MEMS structures that may be used to provide MEMS oscillatory devices 420 of FIG. 4 are described in U.S. Pat. No. 6,485,273 to Goodwin-Johansson, entitled Distributed MEMS Electrostatic Pumping Devices, the disclosure of which is hereby incorporated herein by reference in its entirety as if set forth fully herein. As described in the Abstract of U.S. Pat. No. 6,485,273, a MEMS pumping device driven by electrostatic forces comprises a substrate having at least one substrate electrode disposed thereon. Affixed to the substrate is a moveable membrane that generally overlies the at least one substrate electrode. The moveable membrane comprises at least one electrode element and a biasing element. The moveable membrane includes a fixed portion attached to the substrate and a distal portion extending from the fixed portion and being moveable with respect to the substrate electrode. A dielectric element is disposed between the at least one substrate electrode and the at least one electrode element of the moveable membrane to provide for electrical isolation. See the Abstract of U.S. Pat. No. 6,485,273. Other MEMS structures that may provide MEMS oscillatory flap devices 420 are described in U.S. Pat. Nos. 6,057,520; 6,229,683; 6,236,491; 6,373,682; 6,396,620; and 6,456,420, all to Goodwin-Johansson, the disclosures of all of which are hereby incorporated herein by reference as if set forth fully herein. The design and operation of MEMS flap actuators are well known to those having skill in the art and need not be described further herein. Moreover, the invention shall-not be construed as being limited to the embodiments of MEMS oscillatory flap devices that are described in these patents.

FIG. 5 illustrates other embodiments of MEMS electrostatically actuated flaps that may be used with embodiments of the present invention. As shown in FIG. 5, these flaps comprise a flexible strip 530 including a fixed end 532 and a free end 534 that is opposite the fixed end. An electrostatic actuator 424 is configured to bend the flexible strip 530 to move the free end 534 toward and away from the face 110a in an oscillatory motion. FIG. 6 illustrates a coiled strip 630 that is configured to uncoil and recoil in an oscillatory manner upon actuation of the actuator 424. In other embodiments, a stiff flap may be configured to lift away from the face without much, if any, coiling. FIG. 7 illustrates a rigid strip 730 that is configured to pivot about a fixed end 732 thereof in an oscillatory manner. Finally, FIG. 8 illustrates a cantilevered strip 830, the fixed end 832 of which is spaced apart from the face 110a by a support 836. It will be understood that combinations of the embodiments of FIGS. 4-8 also may be provided. It also will be understood that any of the embodiments of FIGS. 4-8 may be used in an orientation such that the flap(s) extend along the face 110a and oscillate in a direction that also is parallel to the face, similar to embodiments of FIGS. 1A, 1B and 3.

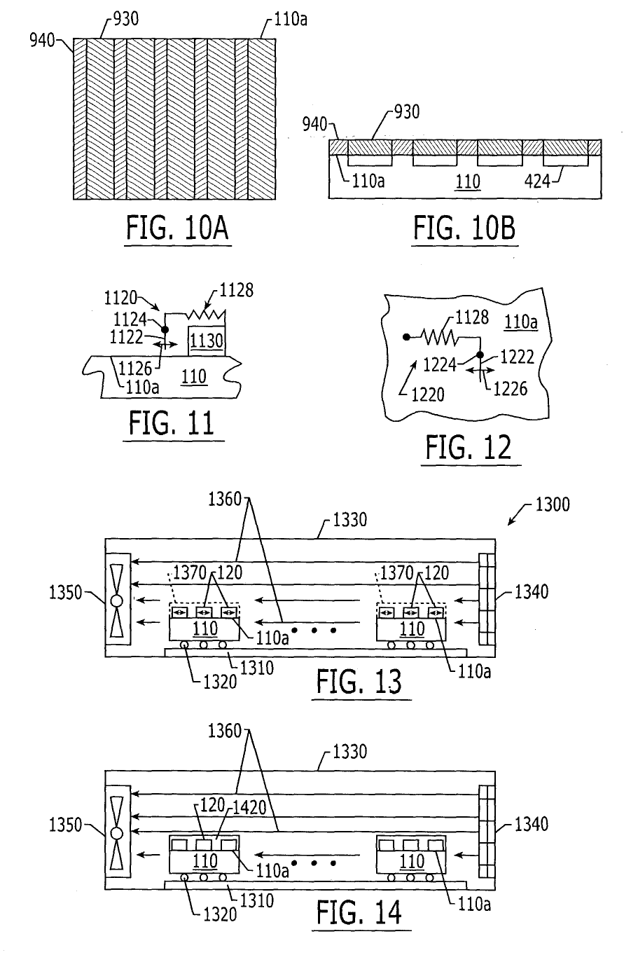

FIGS. 9A-9B and 10A-10B illustrate a specific example of coiled strip MEMS oscillatory devices according to some embodiments of the invention. A 4×4 array is shown, although larger or smaller arrays may be used in other embodiments. FIGS. 9A and 9B are a top plan view and a side cross-sectional views of coiled strip actuators in an unactuated position, wherein the coil strip 930 is anchored to the substrate by an anchor 940 and is coiled in the unactuated position. FIGS. 10A-10B are top plan and side cross-sectional views of these actuators in their actuated positions, wherein electrostatic attraction by the actuators 424 uncoils the coiled strip 930. Microelectromechanical oscillatory devices of these embodiments oscillate between the coiled and uncoiled positions of FIGS. 9A-9B and 10A-10B.

FIGS. 11 and 12 illustrate other embodiments of microelectromechanical oscillatory devices that comprise a plurality of blades and a plurality of microelectromechanical actuators, as were generally described in FIG. 3. More specifically, FIG. 11 is a side cross-sectional view of MEMS oscillatory devices 1120 that include a blade 1122 that extends orthogonal to the face 110a and a MEMS actuator 1128 that is configured to oscillate the blade 1122 in a direction 1126 that is parallel to the face. As shown in embodiments of FIG. 11, the blades 1122 may be pivoted about a pivot 1124 and the MEMS actuator 1128 may be supported by a support 1130. FIG. 12 illustrates other embodiments of MEMS oscillatory devices 1220 wherein blades 1222 extend parallel to the face 110a, and are configured to oscillate in a direction 1226 that is parallel to the face 110a. Actuation takes place by a MEMS actuator 1228 that actuates the blades 1222 about a pivot 1224.

In some embodiments of FIGS. 11 and 12, the MEMS actuators 1128 and 1228 may be embodied by integrated force array MEMS actuators. Integrated force array MEMS actuators are described, for example, in U.S. Pat. No. 5,206,557 to Bobbio entitled Microelectromechanical Transducer and Fabrication Method, the disclosure of which is hereby incorporated herein by reference in its entirety as if set forth fully herein. As described in the Abstract of U.S. Pat. No. 5,206,557, a microelectromechanical transducer includes a plurality of strips arranged in an array and maintained in a closely spaced relation by a plurality of spacers. An electrically conductive layer on portions of the strips and spacers distributes electrical signal within the transducer to cause adjacent portions of the strips to move together. The strips and spacers may be formed from a common dielectric layer using microelectronic fabrication techniques. See the Abstract of U.S. Pat. No. 5,206,557. Other integrated force array devices are described in U.S. Pat. No. 5,290,400 to Bobbio; 5,434,464 to Bobbio et al.; and 5,479,061 to Bobbio et al., the disclosures of all of which are hereby incorporated herein by reference in their entirety as if set forth fully herein. Also see Jacobson, et al., Integrated Force Arrays: Theory and Modeling of static Operation, Journal of Microelectromechanical Systems, Vol. 4, No. 3, September 1995, pp. 139-150, the disclosure of which is hereby incorporated herein by reference in its entirety as if set forth fully herein. The design and operation of integrated force arrays are well known to those having skill in the art and need not be described further herein. It will also be understood that integrated force array structures are not limited to the embodiments shown in these patents.

Microelectromechanical oscillatory devices according to any of the embodiments that were described above in connection with FIGS. 1-12 may be configured to disrupt the thermal boundary layer of a microelectronic substrate. In particular, the microelectronic substrate generates heat during operation thereof, which is removed by a fluid flow adjacent the face. As is well known to those having skill in the art, the fluid flow defines a thermal boundary layer adjacent the face. In some embodiments of the present invention, the plurality of microelectromechanical oscillatory devices are configured to oscillate to disrupt the thermal boundary layer. In some embodiments, the plurality of microelectromechanical oscillatory devices are configured to extend at least partially into the thermal boundary layer. In other embodiments, the plurality of microelectromechanical oscillatory devices are located within the thermal boundary layer. Embodiments of the present invention also may be used with electronic components other than microelectronic devices that generate heat during operation thereof, in any of the configurations that are described herein.

More specifically, FIG. 13 is a schematic diagram of a piece of electronic equipment such as a computer, which includes therein a plurality of microelectronic substrates 110. The microelectronic substrates 110 may be mounted to a second level package 1310 such as a printed circuit board using conventional mounting techniques such as solder bumps 1320. The microelectronic devices 110 are contained within a housing 1330. The housing includes a fluid inlet port, such as an air inlet port 1340, and a fan 1350 that together create a fluid flow 1360 across the faces 110a. The fluid flow 1360 defines a thermal boundary layer 1370 of stagnant fluid, such as stagnant air, adjacent the faces 110a. The plurality of MEMS oscillatory devices 120 are configured to disrupt the thermal boundary layer 1370.

Without wishing to be bound by any theory of operation, it has been theorized, according to some embodiments of the present invention, that a major contributor to the inability to remove heat from an integrated circuit is the thermal boundary layer 1370 adjacent the face of the microelectronic device, which contains stagnant (unmoving) fluid, through which heat transfer occurs mainly by conduction. In contrast, in the fluid flow 1360, heat transfer occurs mainly by convection. Some embodiments of the invention provide MEMS oscillatory devices that extend adjacent and/or at least partially into the thermal boundary layer 1370, to thereby disrupt the thermal boundary layer 1370. An increased amount of heat dissipation may thereby occur by convection rather than conduction. Since the thermal boundary layer 1370 may only need to be disrupted, MEMS oscillatory devices may be used rather than rotary devices such as MEMS fans. As is well known to those having skill in the art, MEMS rotary devices may be unreliable and may fail relatively quickly. In contrast, MEMS oscillatory devices may have much longer reliability and lifetimes.

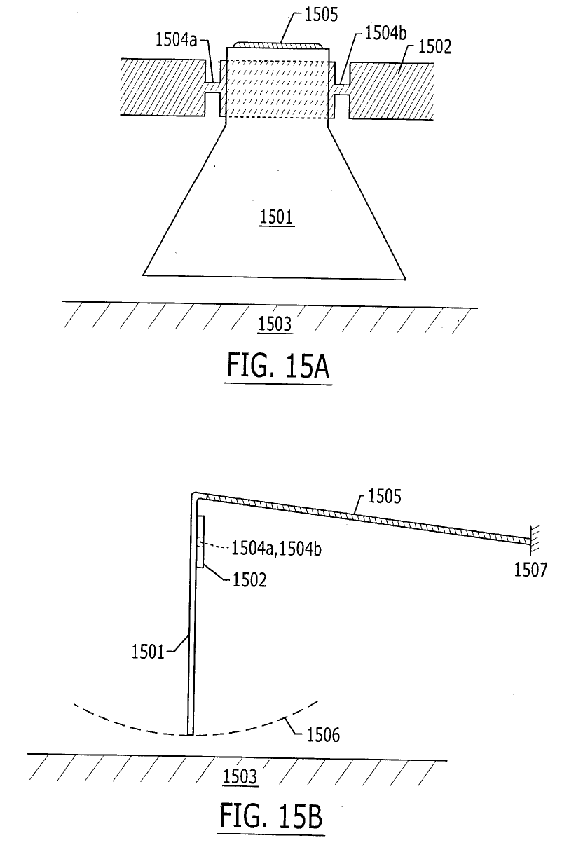

In FIG. 13, the fluid that is used to cool the microelectronic substrates 110 is a gas such as air. In other embodiments of the invention, as shown in FIG. 14, a liquid may be used for at least some of the fluid. In particular, as shown in FIG. 14, a liquid 1420 is provided on the face 110a, for example by encapsulating the liquid 1420 on the face 110a using conventional techniques. The microelectromechanical oscillatory devices 120 are contained at least partially within the liquid. In some embodiments, liquid coolant may be pumped onto at least part of a face of a microelectronic substrate and the microelectromechanical oscillating devices may be used within the liquid coolant.

In any of the above-described embodiments, the plurality of MEMS oscillatory devices may be powered and/or controlled directly from the microelectronic substrate 110. Thus, the substrate 110 may be configured to change the timing, number, frequency and/or other parameters of the MEMS oscillatory devices as a function, for example, of the heat that is generated by the substrate, and may also be configured to activate and/or shut down some or all of the MEMS oscillatory devices as a function of heat that is measured and/or other parameters such as duty cycle or load on the devices in the substrate. However, it will be understood that, in other embodiments, external power and/or control for the MEMS oscillatory devices may be provided.

It will be understood that other embodiments of the present invention can use any electromechanical device that is configured to disrupt the thermal boundary layer by movement thereof MEMS devices, non-MEMS devices, rotary devices and/or oscillatory devices may be provided that are configured to disrupt the thermal boundary layer, to thereby allow increased heat dissipation by convection rather than by conduction. In some embodiments, these electromechanical devices are configured to sweep the thermal boundary layer in a direction that is parallel to the face. The electromechanical devices may be oriented in any of the orientations that are described herein and/or other orientations.

Thus, embodiments of the present invention may be used with microelectronic devices including integrated circuits, power devices and/or optoelectronic devices, and may also be used with other heat-producing components that are not microelectronic devices. Moreover, MEMS oscillatory devices may be used in some embodiments, whereas conventional non-MEMS oscillatory devices may be used in other embodiments. In still other embodiments, other microelectromechanical or electromechanical devices that are configured to disrupt the thermal boundary layer by movement thereof may be used. Embodiments of the present invention also may provide cooling devices for a microelectronic substrate or other components that produce heat, wherein the cooling devices comprise MEMS oscillatory devices, non-MEMS oscillatory devices, MEMS devices that disrupt the thermal boundary layer and/or non-MEMS electromechanical devices that disrupt the thermal boundary layer. Methods of manufacturing microelectronic devices and/or other devices, and methods of cooling these devices also may be provided according to embodiments of the present invention.

Additional theoretical discussions of some embodiments of the present invention now will be provided. These theoretical discussions shall not be construed as limiting the present invention.

Some embodiments of the present invention use an approach to microprocessor cooling, and microelectronic or other device cooling generally, employing microfabricated actuators. Some embodiments make use of boundary layer disruption. A boundary layer may be defined as a thin region near a solid object within a moving fluid (gas or liquid) where viscous effects are important. That is, as a fluid moves past a solid object, some of this fluid, located at a great distance from the solid object, behaves as if the object were not there. In contrast, fluid located close to the object interacts with the surface of the object, adhering to it, and at the immediate surface the velocity of the fluid is essentially no different than that of the surface, typically zero for an electronic component that is not moving. Adjacent to this fluid, other fluid is coupled mechanically to the distant but freely moving fluid through the boundary layer via viscous effects. The thickness of the boundary layer is sometimes determined as the distance from the surface at which the flowing fluid reaches 99% of its “free stream” velocity.

Boundary layers are typically modest in thickness, but they can also be relatively large. For example, the boundary layer for a 5-meter long automobile traveling 120 km/hr in still air may be about 8 cm. The boundary layer for a 40-meter long submarine traveling 70 km/hr in water (higher viscosity than air) may be about 48 cm. For an object, the surface of which is parallel to the direction of fluid flow, the boundary layer at the object's trailing edge may be greater than at the leading edge. For stationary or very slowly moving objects, or slowly moving fluid streams, the boundary layer may be fully established. During acceleration or deceleration of flow, there may be non-steady state effects, adding a temporal component and further complexity to the boundary layer. However, even during steady state, there may be pressure gradients (pressure as a function of distance from the solid surface) as well as thermal gradients (temperature as a function of distance from the solid surface) that may appear quite different from each other. If one knows the temperature of the surface and of a known fluid moving at a defined velocity and other dimensions, a thermal boundary layer may be designated and measured.

A mathematical definition of a boundary layer may depend upon many different parameters. However, for a flat plate with incompressible flow, a viscous boundary layer thickness may be given approximately by:

d/x=5[Re]^{-½}. (1)

Stated in words, the ratio of viscous boundary layer thickness d to the distance from the leading edge of a flat plate in a flowing fluid stream x is equal to about 5 times the reciprocal of the square root of the Reynolds number at point x. The Reynolds number is dimensionless and is the ratio of inertial to viscous forces in a moving fluid. The Reynolds number in a circular pipe with fluid flowing may be given by:

Re=Dvp/u, (2)

where: Re=Reynolds number;

D=internal diameter of pipe;

v=mean velocity of fluid;

p=density of fluid; and

u=viscosity of fluid.

The thermal boundary layer is typically the same as the viscous boundary layer, and may be superimposed therewith. However, this may not be true in all cases. The viscous boundary layer is characterized by shear and velocity gradients. In contrast, the thermal boundary layer is characterized by temperature gradients and heat transfer. The Prandtl number may be used to determine how closely the thermal boundary layer corresponds with the viscous boundary layer, as shown in Equation (3):

Pr=Cu/K, (3)

where: Pr=Prandtl number;

C=heat capacity of the fluid;

u=viscosity of the fluid; and

K=thermal conductivity of the fluid.

The thermal boundary layer is thicker and extends further above the surface of the flat plate and the viscous boundary layer line for fluids where Pr is much less than 1. The thermal boundary layer is thinner than the viscous boundary layer and does not extend as far above the surface of the flat plate for fluids where Pr is much greater than 1. Pr may vary between 0.2 for most molten metals at the low end and over 100 for some liquids. However, Pr is about 1 for most gases and for water. In particular, Pr=0.74 for diatomic gases and 0.80 for triatomic gases. Pr=1.0 for water at 160° F. and 5 for water at 45° F. Accordingly, for air-cooled microchips, the two boundary layers may be considered superimposable. For liquid coolants, the situation may be different. Additional discussion of viscous and thermal boundary layers may be found in standard textbooks that describe fluid dynamics, and need not be provided herein.

Heat flow from a surface that is hot relative to the fluid that surrounds it occurs via convection, conduction, and/or radiation. The “layers” of fluid in the vicinity of the surface tend to trap heat and to insulate the surface from cooler layers. Thus, the boundary layer may limit or prevent convection, so that heat transfer through the boundary layer may occur primarily via conduction. Conduction, especially in most fluids, generally is a slower process for heat removal than convection, so the temperature tends to rise. Some embodiments of the present invention can increase convection by dispersing the layers nearest to the surface and generally disrupting the boundary layer such that a greater amount of heat may be removed from the surface by convection, and therefore the surface temperature may decrease.

Dispersing insulating layers of fluid may also increase radiation from a hot surface to its cooler surroundings to allow additional heat removal. It has been long known in the art of heat transfer technology that more heat may be transferred from a surface in contact with fluid if the flow is turbulent, as opposed to laminar, all other variables being equal. This is thought to derive directly from the observation that heat generally flows through the laminar layers by conduction, which calls for a steep temperature gradient in most fluids because of low thermal conductivity. Embodiments of the present invention can achieve at least some boundary layer disruption and degradation of laminar layers, and thus can improve heat transfer and provide a greater cooling effect for a surface in a reservoir of fluid at a lower mean temperature than this surface.

In some embodiments, boundary layer disruption is brought about via oscillation of one or more blades or flaps sweeping within the thermal boundary layer, using an appropriate actuator. A MEMS actuator may be most appropriate for powering blades or flaps of the type described herein, especially when a macroscopic driver, e.g. an electric motor would not be suitable because of space limitations and/or heat production issues. A variety of MEMS actuators may be employed, but some embodiments use a MEMS actuator of the contractile electrostatic type, also referred to as an integrated force array, to power a tiny blade in the vicinity of the surface to be cooled. A discussion of the configuration and deployment of this type of actuator for this application, according to some embodiments of the present invention, now will be provided.

The use of an appropriate MEMS actuation scheme to disrupt the boundary layer need not contribute measurably to heat production via its action and can result in considerable cooling. In contrast, the boundary layer could be disrupted using ultrasound of the appropriate frequency coupled into the fluid to produce cavitation. The use of ultrasonic energy can disrupt the boundary layer but may also generate considerable heat. Moreover, the oscillatory MEMS actuators used in some embodiments of the present invention, unlike rotating and sliding MEMS systems, may not produce measurable friction and may not wear down due to frictional forces. Ordinary frictional forces may scale to enormous proportions in the micro world and may wreak havoc upon rotary devices such as tiny MEMS fans, turbines, and rotors.

Embodiments of the present invention may be used in conjunction with other cooling methods, such as refrigeration systems, macroscopic fans that move masses of air, liquid coolants propelled past or surrounding or adjacent to heat producing components, conventional heat sinks, compartments with cooled walls that encase heat producing components, and/or other cooling methods.

Other embodiments of the present invention that provide oscillating blades, also referred to herein as micro-blades, as were generally described in FIGS. 3, 11 and 12, will now be described. FIGS. 15A and 15B shows a micro-blade 1501 supported by a frame 1502 as part of a system in close proximity to the surface 1503 of a heat-producing electronic component (e.g., a microchip) in a fluid environment. FIG. 15A is a front view and FIG. 15B is a side view. Cooling is desired for the electronic component via heat removal from its surface 1503. These embodiments of the micro-blade system includes a thin micro-blade 1501 in the shape of trapezoid with a rectangular extension at the smaller trapezoid base. The rectangular section of the micro-blade 1501 is bonded to a platform, most of which is shown hidden in FIG. 15A behind the rectangular section of the micro-blade. Alternatively, the micro-blade could be formed as an extension of the platform itself. The platform is part of the frame 1502 and able to swing freely via torsion hinges 1504a and 1504b, which are also part of the frame 1502 in this embodiment. The platform and the micro-blade attached thereto are driven into oscillation by an electrostatic actuator 1505. This actuator acts as an energized spring, alternatively compressing and relaxing as potential is applied from a voltage source (not shown) at a predetermined frequency. The frequency may be chosen to drive the micro-blade system at a resonance point to provide the greatest angular displacement of the blade as it waves back and forth.

In FIG. 15B, the micro-blade system is shown in side view, enabling the actuator to be shown in perspective (but not necessarily to scale) along with the micro-blade 1501, the frame 1503 with torsion hinges (1504a, 1504b), the surface 1503, and a stationary support 1507 that is fixed in position relative to the surface 1503. The stationary support 1507 need not be attached to the surface 1503 or to the electronic component to be cooled. Also shown in FIG. 15B is the arc 1506 swept out by the leading edge of the oscillating micro-blade 1501. Thus, in FIGS. 15A and 15B, the blade 1501 extends generally orthogonal to the surface 1503 and oscillates in a direction 1506 that is generally parallel to the surface 1503.

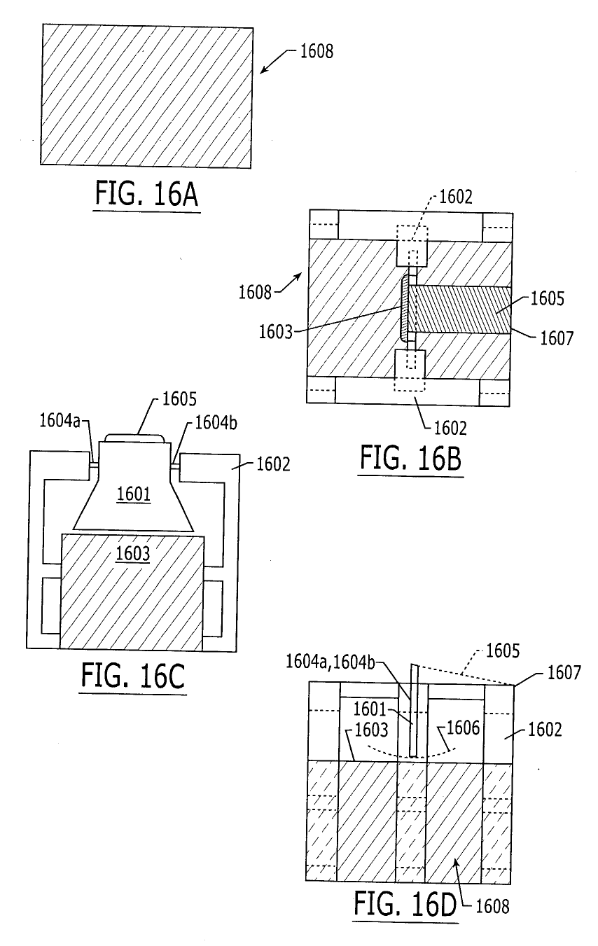

FIGS. 16A-16D show embodiments in which a micro-blade system is attached directly to the electronic component 1608 to be cooled. FIG. 16A shows a top view of the native component. FIG. 16B shows a top view of a micro-blade system with a frame 1602, which is formed into a scaffold fitted to the shape of the electronic component and affixed thereto by mechanical means (e.g. force fitted, held via spring clips, bonded, etc.). The actuator 1605 is visible above the surface 1603 of the electronic component 1608. One end of the actuator is affixed to the micro-blade (not shown) and the other end is affixed to a stationary point 1607 of the frame 1602, although this detail is not shown (in the figure. In FIG. 16C, a front view of the micro-blade system is shown. In this figure the torsion hinges 1604a and 1604b are visible along with the micro-blade 1601 with the actuator 1605 connected to the top of the micro-blade and the surface 1603 below. FIG. 16D shows a side view of the micro-blade system with the frame scaffold 1602, the micro-blade 1601, its sweeping arc 1606, the actuator 1605, the fixed support 1607, the torsion hinges 1604a and 1604b, the electronic component 1608, and its surface 1603.

In some embodiments, to achieve a greater cooling effect, a greater disruption of the boundary layer may be desired. If one blade is insufficient to achieve the desired cooling effect, a plurality of blades may be used, driven by the same actuator and/or by independent actuators.

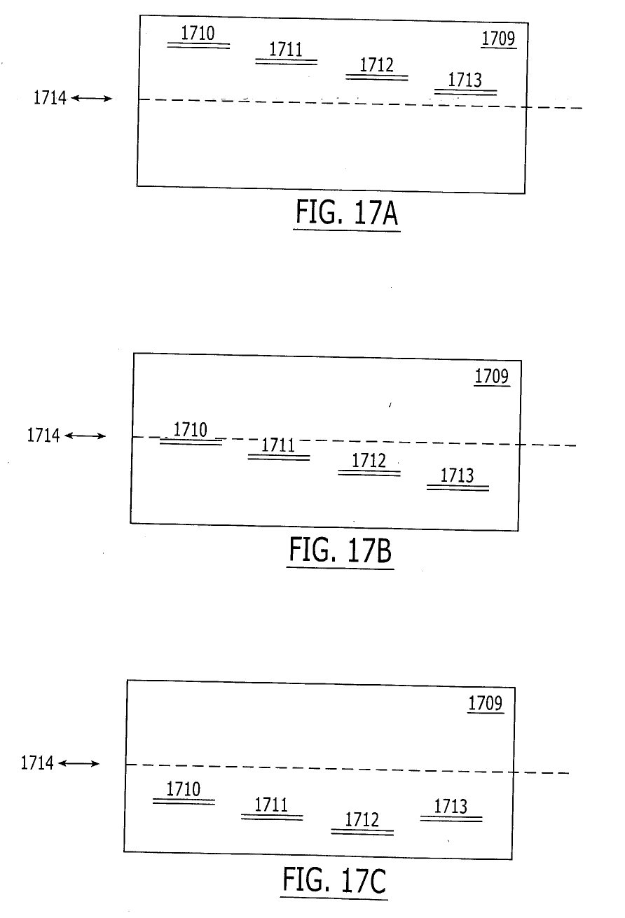

FIGS. 17A-17C show a top view of an embodiment of a micro-blade system including four blades 1710-1713, each mounted to independently swinging platforms (not shown) supported by a common frame (not shown). In FIGS. 17A-17C, only the blade edge closest to the surface of the electronic component 1709 is shown for each micro-blade in cross section above the outline of the electronic component 1709. The fans 1710-1713 are driven via their respective platforms by independent actuators (not shown). The actuators may be energized by asynchronous sets of waveforms, such that they are driven to a greater or lesser degree out of phase with each other.

Using an actuation scheme of this type, each micro-blade edge, as it is driven back and forth along its arc of travel, sweeps to either side of an imaginary reference line 1714 extending longitudinally across the surface of the electronic component 1709. Each micro-blade therefore sweeps fluid laterally to either side of the reference line. The phase relationship of the blades enables a net transfer of fluid longitudinally along the direction of the reference line 1714, as well. Thus, the boundary layer is disrupted laterally and longitudinally as the micro-blades follow a wave-like propagation path.

This motion is brought out in the sequence of events, starting with FIG. 17A, where the micro-blades can be seen above the reference line 1714 and moving toward it. In FIG. 17A, the first micro-blade 1710 is at the extreme end of its arc of travel. In FIG. 17B, a very short time later, the micro-blades have advanced to new positions, having crossed the reference line 1714, and are now moving past and away from the reference line. The first micro-blade 1710 has just crossed reference line 1714, and the other micro-blades are well past it. In FIG. 17C, the first micro-blade 1710 is well past reference line 1714. The second micro-blade 1711 is approaching the end of its arc. The third micro-blade 1712 is at the end of its arc, and the fourth micro-blade 1713 has completed its arc, reversed direction, and is now moving toward the reference line 1714.

A micro-blade may assume a variety of shapes, depending upon the application. If the micro-blade is to be situated within an air space of a heat sink or cooling fin, a shorter geometry may be used compared to that of the long trapezoidal fan shape shown in FIGS. 15 and 16. The micro-blade can also have a sector shape, as cut from a circle, or even a square or triangular shape. Many other shapes are possible. The micro-blade can be flexible, to the extent that it deforms slightly as it is driven back and forth, allowing somewhat thinner materials to be used in its fabrication. A micro-blade can also be fabricated from a variety of materials, for example polyimide, polyester, titanium, carbon, silicon, titanium, iron alloys, carbon nanotube composites and stiffened silks, to name a few.

In some embodiments, the leading edge of the micro-blade is situated close to the surface from which heat is to be removed to enable a greater degree of disruption of the layers of fluid closest to the surface. It is possible to power micro-blades from a distance, for example using a miniature speedometer-type cable connected to a conventional electric motor. However, for small electronic devices, such as laptop, notebook, and hand-held computers, the size, power requirements and overall heat production of an electric motor may be counter productive.

MEMS actuators are very small and can be highly efficient. Therefore a MEMS actuator may be used in many embodiments of the present invention. In general, when a MEMS actuator is used to drive a micro-blade, the micro-blade system can be situated in close proximity to the surface to be cooled. However, locating the micro-blade itself, or structures associated with it, directly on the surface to be cooled may create eddies and give rise to stagnant pooling or entrapment of fluid in some embodiments. Such stagnant pooling and/or entrapment of fluid could create “hot spots” and become counterproductive in some embodiments. Similarly, the fluid may be driven with an appropriate oscillating frequency. Desirable frequencies may be higher for gases, such as air, and correspondingly lower for liquids in some embodiments, since the viscosities of liquids are much greater. Aside from requiring more driving energy, the use of very high frequencies may result in heating the fluid. In air, frequencies for achievement of cooling may be expected to be below 5,000 Hz and generally below 500 Hz. It may be expected that frequencies below 50 Hz may be adequate for most applications where air is the fluid.

In an electrostatic-type MEMS flap actuator, of the type described, the fluid medium also may become the dielectric material for the capacitive elements of the actuator. In some embodiments, the actuator is isolated from the fluid by encasing it in a bladder or similar structure containing a fluid of choice. In such embodiments, the contained fluid may be chosen for its superior dielectric properties.

In some embodiments, the micro-blade may have a textured surface. The texturing may include a pattern of shapes, e.g. small hexagons raised slightly on both surfaces of the blade. An alternative surface for a blade may include a flat substrate, typically 25 to 100 microns thick with either stiff or flexible needle-like projections (or a combination of both types) on both surfaces. In such a configuration, the needle-like projections of about 5 μm to about 20 μm mean diameter and up to about 100 μm or more long could have a relatively high density and be spaced about 25 μm to about 100 μm apart. These projections could be positioned at right angles to the plane of the substrate but could also project at an angle of 30° or perhaps even less. Projections could also be used on the edge of the micro-blade. Such textures and/or projections may increase the ability of the blade to move fluid and break up laminar fluid layers.

The appropriate textures and/or projections may be fabricated by various methodologies known in the art of microfabrication. Such projections or high aspect ratio patterns, in general, could be formed by processes such as: chemical etching, electrodeposition or micromachining via electron beam or laser beam. Alternatively, LIGA [the German acronym for X-ray lithographic (X-ray lithography), galvanoformung (electrodeposition) and abformtechnik (molding)] could be used to provide efficient high volume production. Other possible production methods include self-assembly strategies and a variety of other possible techniques including magnetic orientation of structures prior to hardening with UV-curable or epoxy adhesive. Alternatively, fabrication of suitable textured surfaces could be prepared using adhesive coating of the substrate and aerosol deposition of freely suspended shaped particles on the substrate to create projections or surface structures.

The following Examples shall be regarded as merely illustrative and shall not be construed as limiting the invention.

### EXAMPLE 1

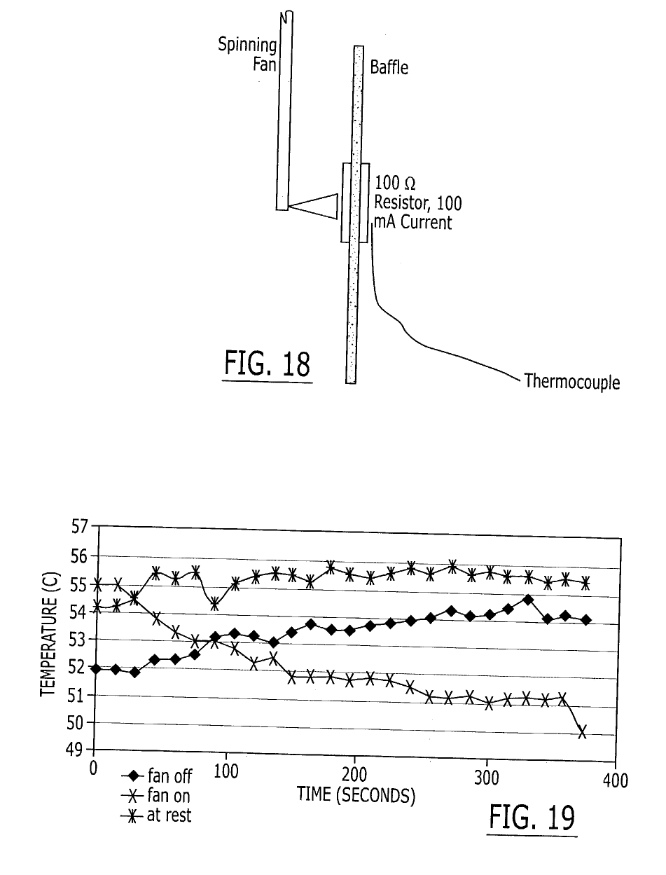

As shown in FIG. 18, a 100-ohm ceramic resistor of rectangular-shape (22 mm×9 mm×9 mm) was placed in slot of equivalent projected area (22 mm×9 mm) in a thin (2 mm) section of cardboard of approximately 30 cm×30 cm. The cardboard was used as a convection barrier (baffle) to isolate one face of the resistor from convective heat transfer at the other face. Thus, heat transfer from one face of the resistor to the other could take place only via heat conduction through the resistor itself. On one side of the cardboard, a copper-constantan thermocouple probe tip, connected to a microprocessor (digital) thermometer, was placed in contact with the resistor surface, such that the thermocouple tip rested gently on the surface. On the opposing surface of the resistor, on the other side of the cardboard barrier, a fan blade was positioned with a driving source. The fan blade was shaped as a trapezoid 8 mm high, with a base of 3.2 mm and a width of 1.6 mm. The fan blade thickness was 76 μm. In initial experiments, the blade was affixed at a right angle with epoxy resin to an electric drill bit (like a flag on a flagpole with the widest base of the trapezoid farthest from the drill bit) and positioned such that when the drill was energized, the fan blade edge at the widest base of the trapezoid would sweep across the resistor surface (face) in its the central portion at a distance of 5 mm during closest approach. See FIG. 18.

When the resistor leads were connected to a 10-volt direct current power source, the resistor was observed to heat to a steady state temperature of 55° C., as measured with the thermocouple thermometer. Room temperature was approximately 24° C. After approximately 10 minutes, the fan blade was energized. The drill bit was spun at a frequency of approximately 42 Hz. The angular frequency was measured with a stroboscope. Within 60 seconds, the temperature was observed to drift downward, reaching a steady state level of approximately 51° C. within 400 seconds. See FIG. 19. Thus, this Example provides preliminary evidence of the potential beneficial effect of disruption of the thermal boundary layer.

### EXAMPLE 2

A MEMS integrated force actuator of the contractile electrostatic type described above was utilized instead of the electric drill in the same experimental setup. The actuator was fabricated from a micromachined polyimide sheet 2.2 microns thick, 3 mm wide and 10 mm long with opposing metallized plates in each micro-cell. Positive and negative triangular pulse trains, out of phase with each other, were used to power the actuator. Opposing plates in the capacitive micro-cells of the actuator were thus supplied continuously with +40 volt and −40 volt pulses, respectively, with the bases of both triangle waves set at zero. It was demonstrated that a back and forth fanning frequency of 42 Hz could be achieved, creating a reciprocating fanning effect analogous to but different from that in Example 1. When driven as in Example 2, the leading edge of the micro-fan was operating near the warm surface at all times and did not move further away every half cycle, as with the circular motion in Example 1. Cooling data was not collected for this device.

### EXAMPLE 3

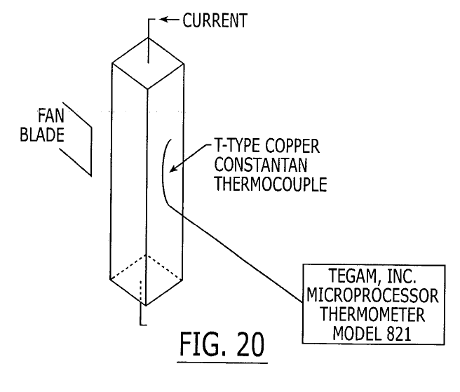

This Example used a piezoelectric fan blade, which is a solid state device whose oscillating Mylar blade is driven at resonance by a piezo bending electric element. The particular piezoelectric fan blade is distributed by Piezo Systems, Inc., Cambridge, Mass., and is described for example at piezo.com/rfn1005.html. In this Example, the same configuration as was described in Examples 1 and 2 is used, except that a 50 ohm ceramic resistor was used with 7.5VAC applied thereto. The piezoelectric fan-blade extended orthogonal to the resistor body, with the fan blade free end adjacent the resistor body as shown in FIG. 20. In FIG. 20, the isolation cardboard is not shown for clarity. The fanning frequency was 60 Hz. The width of the piezoelectric fan blade was 12.7 mm. The ceramic (wire wound) resistor was 9 mm×9 mm×47 mm in size. The surface area of one face was 9×47=423 mm². The following Table illustrates the starting temperature, temperature at 3 minutes and temperature at 10 minutes as a function of distance of the edge of the fan blade from the surface of the resistor.

TABLE

| Distance From | Starting | | |
|---|---|---|---|
| Surface | Temp (° C.) | Temp at t = 3 min. | Temp at t = 10 min. |
| .005″ | 49.1 | 36.1 | 35.5 |
| .005″ | 50.8 | 38.0 | 36.1 |
| .005″ | 51.0 | 38.5 | 36.3 |
| .021″ | 49.2 | 37.3 | 35.5 |
| .021″ | 49.5 | 37.6 | 35.5 |
| .070″ | 51.2 | 38.9 | 36.5 |
| .070″ | 51.5 | 38.6 | 36.4 |
| .151″ | 50.6 | 38.9 | 36.6 |
| .151″ | 51.2 | 38.8 | 36.5 |
| .316″ | 51.3 | 39.7 | 37.3 |
| .316″ | 51.4 | 39.6 | 37.2 |
| .625″ | 50.5 | 40.8 | 38.6 |
| .625″ | 51.0 | 41.2 | 38.5 |
| 1.25″ | 50.2 | 42.5 | 39.9 |
| 1.25″ | 51.0 | 43.0 | 40.2 |

As clearly shown, an increased cooling effect may be provided, independent of temperature, when the fan blade is relatively close to the surface. This provides additional preliminary data that disruption of the boundary layer may provide beneficial results.

In the drawings and specification, there have been disclosed embodiments of the invention and, although specific terms are employed, they are used in a generic and descriptive sense only and not for purposes of limitation, the scope of the invention being set forth in the following claims.

What is claimed is:

1. A microelectronic device comprising:
a microelectronic substrate including a face; and
a plurality of microelectromechanical oscillatory devices adjacent the face that are configured to oscillate to dissipate at least some heat that is generated by the microelectronic substrate during operation thereof.

2. A microelectronic device according to claim 1 wherein the plurality of microelectromechanical oscillatory devices are configured to oscillate in a direction that is parallel to the face.

3. A microelectronic device according to claim 1 wherein the plurality of microelectromechanical oscillatory devices are configured to oscillate in a direction that is orthogonal to the face.

4. A microelectronic device according to claim 1 wherein the plurality of microclectromechanical oscillatory devices comprise a plurality of blades and a plurality of microelectromechanical actuators, a respective one of which is configured to oscillate a respective one of the blades.

5. A microelectronic device according to claim 4 wherein the plurality of blades extend along the face and wherein the plurality of microelectromechanical actuators are configured to oscillate the plurality of blades in a direction that is parallel to the face.

6. A microelectronic device according to claim 4 wherein the plurality of blades extend orthogonal to the face and wherein the plurality of microelectromechanical actuators are configured to oscillate the plurality of blades in a direction that is parallel to the face.

7. A microelectronic device according to claim 4 wherein the plurality of blades extend oblique to the face and wherein the plurality of microelectromechanical actuators are configured to oscillate the plurality of blades in a direction that is parallel to the face.

8. A microelectronic device according to claim 4 wherein the plurality of microelectromechanical actuators comprises a plurality of integrated force arrays.

9. A microelectronic device according to claim 1 wherein the plurality of microelectromechanical oscillatory devices comprise a plurality of flaps and a plurality of microelectromechanical actuators, a respective one of which is configured to oscillate a respective one of the flaps.

10. A microelectronic device according to claim 9 wherein the plurality of flaps extend along the face and wherein the plurality of microelectromechanical actuators are configured to oscillate the plurality of flaps in a direction that is orthogonal to the face.

11. A microelectronic device according to claim 9 wherein the plurality of microelectromechanical oscillatory devices comprise a plurality of electrostatically actuated flaps.

12. A microelectronic device according to claim 9 wherein the plurality of flaps each comprises a strip including a fixed end and a free end that is opposite the fixed end.

13. A microelectronic device according to claim 12 wherein the strip is configured to pivot about the fixed end in an oscillatory manner.

14. A microelectronic device according to claim 12 wherein the strip is configured to bend in an oscillatory manner.

15. A microelectronic device according to claim 12 wherein the strip is configured to uncoil and recoil in an oscillatory manner.

16. A microelectronic device according to claim 12 wherein the fixed end is spaced apart from the face.

17. A microelectronic device according to claim 1 wherein the plurality of microelectromechanical oscillatory devices are arranged on the face in a regular array.

18. A microelectronic device according to claim 1 wherein the plurality of microelectromechanical oscillatory devices are arranged on the face in a random array.

19. A microelectronic device according to claim 1 wherein at least some heat that is generated by the microelectronic device during operation thereof is removed by a fluid flow that defines a thermal boundary layer, and wherein the plurality of microelectromechanical oscillatory devices are configured to oscillate to disrupt the thermal boundary layer.

20. A microelectronic device according to claim 19 wherein the plurality of microelectromechanical oscillatory devices are configured to extend at least partially into the thermal boundary layer.

21. A microelectronic device according to claim 19 wherein the plurality of microelectromechanical oscillatory devices are configured to extend adjacent the thermal boundary layer.

22. A microelectronic device according to claim 19 wherein the plurality of microelectromechanical oscillatory devices are located within the thermal boundary layer.

23. A microelectronic device according to claim 19 wherein the fluid is a liquid and/or a gas.

24. A microelectronic device according to claim 1 further comprising a liquid on the face and wherein the plurality of microelectromechanical oscillatory devices are contained at least partially within the liquid.

25. A microelectronic device according to claim 1 wherein the face is a first face, the microelectronic substrate comprising a second face opposite the first face and a plurality of mounting structures on the second face.

26. A microelectronic device according to claim 1 wherein the face is contained in an ambient fluid and wherein the plurality of microelectromechanical oscillatory devices are configured to oscillate to sweep the ambient fluid in a direction that is parallel to the face.

27. A microelectronic device according to claim 1 wherein at least two of the plurality of microelectromechanical oscillatory devices are configured to oscillate at different frequencies.

28. A microelectronic device according to claim 1 wherein the plurality of microelectromechanical oscillatory devices are configured to oscillate in response to electrostatic, magnetic and/or piezoelectric actuation.

29. A microelectronic device according to claim 1 wherein the plurality of microelectromechanical oscillatory devices are on the face.

30. A microelectronic device comprising:
a microelectronic substrate including a face, the microelectronic substrate generating heat during operation thereof that is removed by a fluid flow that defines a thermal boundary layer adjacent the face; and
at least one electromechanical device that is configured to disrupt the thermal boundary layer by movement thereof.

31. A microelectronic device according to claim 30 wherein the at least one electromechanical device comprises at least one electromechanical oscillatory 30 device adjacent the face.

32. A microelectronic device according to claim 31 wherein the at least one electromechanical oscillatory device is configured to oscillate in a direction that is parallel to the face.

33. A microelectronic device according to claim 31 wherein the at least one electromechanical oscillatory device is configured to oscillate in a direction that is orthogonal to the face.

34. A microelectronic device according to claim 31 wherein the at least one electromechanical oscillatory device comprises at least one blade and at least one electromechanical actuator, a respective one of which is configured to oscillate a respective one of the blades.

35. A microelectronic device according to claim 30 wherein the at least one electromechanical device comprises at least one microelectromechanical device.

36. A heat producing component comprising:
a substrate including a face; and
a plurality of microelectromechanical oscillatory devices adjacent the face that are configured to oscillate to dissipate at least some heat that is generated by the substrate during operation thereof.

37. A component according to claim 36 wherein the plurality of microelectromechanical oscillatory devices are configured to oscillate in a direction that is parallel to the face.

38. A component according to claim 36 wherein the plurality of microelectromechanical oscillatory devices are configured to oscillate in a direction that is orthogonal to the face.

39. A component according to claim 36 wherein the plurality of microelectromechanical oscillatory devices comprise a plurality of blades and a plurality of microelectromechanical actuators, a respective one of which is configured to oscillate a respective one of the blades.

40. A component according to claim 36 wherein the plurality of microelectromechanical oscillatory devices comprise a plurality of flaps and a plurality of microelectromechanical actuators, a respective one of which is configured to oscillate a respective one of the flaps.

41. A component according to claim 36 wherein at least some heat that is generated by the substrate during operation thereof is removed by a fluid flow that defines a thermal boundary layer, and wherein the plurality of microelectromechanical oscillatory devices are configured to oscillate to disrupt the thermal boundary layer.

42. A component according to claim 41 wherein the fluid is a liquid and/or a gas.

43. A component according to claim 36 wherein the plurality of microelectromechanical oscillatory devices are on the face.

44. A heat producing component comprising:
a substrate including a face, the substrate generating heat during operation thereof that is removed by a fluid flow that defines a thermal boundary layer adjacent the face; and
at least one electromechanical device that is configured to disrupt the thermal boundary layer by movement thereof.

45. A component according to claim 44 wherein the at least one electromechanical device comprises at least one electromechanical oscillatory device adjacent the face.

46. A component according to claim 45 wherein the at least one electromechanical oscillatory device is configured to oscillate in a direction that is parallel to the face.

47. A component according to claim 45 wherein the at least one electromechanical oscillatory device is configured to oscillate in a direction that is orthogonal to the face.

48. A component according to claim 45 wherein the at least one electromechanical oscillatory device comprises at least one blade and at least one electromechanical actuator, a respective one of which is configured to oscillate a respective one of the blades.

49. A cooling device for a microelectronic substrate that includes a face, comprising:
a plurality of microelectromechanical oscillatory devices-that are configured for mounting adjacent the face and are configured to oscillate to dissipate at least some heat that is generated by the microelectronic substrate during operation thereof.

50. A device according to claim 49 wherein the plurality of microelectromechanical oscillatory devices are configured to oscillate in a direction that is parallel to the face.

51. A device according to claim 49 wherein the plurality of microelectromechanical oscillatory devices are configured to oscillate in a direction that is orthogonal to the face.

52. A device according to claim 49 wherein the plurality of microelectromechanical oscillatory devices comprise a plurality of blades and a plurality of microelectromechanical actuators, a respective one of which is configured to oscillate a respective one of the blades.

53. A device according to claim 49 wherein the plurality of microelectromechanical oscillatory devices comprise a plurality of flaps and a plurality of microelectromechanical actuators, a respective one of which is configured to oscillate a respective one of the flaps.

54. A device according to claim 49 wherein at least some heat that is generated by the microelectronic device during operation thereof is removed by a fluid flow that defines a thermal boundary layer, and wherein the plurality of microelectromechanical oscillatory devices are configured to oscillate to disrupt the thermal boundary layer.

55. A method of cooling a microelectronic substrate including a face, the method comprising:
mounting a plurality of microelectromechanical oscillatory devices adjacent the face that are configured to oscillate to dissipate at least some heat that is generated by the microelectronic substrate during operation thereof.

56. A method according to claim 55 wherein the plurality of microelectromechanical oscillatory devices are configured to oscillate in a direction that is parallel to the face.

57. A method according to claim 55 wherein the plurality of microelectromechanical oscillatory devices are configured to oscillate in a direction that is orthogonal to the face.

58. A method according to claim 55 wherein the plurality of microelectromechanical oscillatory devices comprise a plurality of flaps and a plurality of microelectromechanical actuators, a respective one of which is configured to oscillate a respective one of the flaps.

59. A method according to claim 55 wherein at least some heat that is generated by the microelectronic substrate during operation thereof is removed by a fluid flow that defines a thermal boundary layer, and wherein the plurality of microelectromechanical oscillatory devices are configured to oscillate to disrupt the thermal boundary layer.

60. A method according to claim 55 wherein the face is contained in an ambient fluid and wherein the plurality of microelectromechanical oscillatory devices are configured to oscillate to sweep the ambient fluid in a direction that is parallel to the face.

61. A method of cooling a microelectronic substrate that includes a face and that generates heat during operation thereof that is removed by a fluid flow that defines a thermal boundary layer adjacent the face, the method comprising:
providing at least one electromechanical device that is configured to disrupt the thermal boundary layer by movement thereof.

62. A method according to claim 61 wherein the at least one electromechanical device comprises at least one electromechanical oscillatory device adjacent the face.

63. A method according to claim 62 wherein the at least one electromechanical oscillatory device is configured to oscillate in a direction that is parallel to the face.

64. A method according to claim 62 wherein the at least one electromechanical oscillatory device is configured to oscillate in a direction that is orthogonal to the face.

65. A method according to claim 62 wherein the at least one electromechanical oscillatory device comprises at least one blade and at least one electromechanical actuator, a respective one of which is configured to oscillate a respective one of the blades.

66. A method according to claim 61 wherein the at least one electromechanical device comprises at least one microelectromechanical device.

67. A method of cooling a microelectronic substrate including a face, the method comprising:
oscillating a plurality of microelectromechanical oscillatory devices adjacent the face to dissipate at least some heat that is generated by the microelectronic substrate during operation thereof.

68. A method according to claim 67 wherein the plurality of microelectromechanical oscillatory devices are configured to oscillate in a direction that is parallel to the face.

69. A method according to claim 67 wherein the plurality of microelectromechanical oscillatory devices are configured to oscillate in a direction that is orthogonal to the face.

70. A method according to claim 67 wherein the plurality of microelectromechanical oscillatory devices comprise a plurality of flaps and a plurality of microelectromechanical actuators, a respective one of which is configured to oscillate a respective one of the flaps.

71. A method according to claim 67 wherein at least some heat that is generated by the microelectronic substrate during operation thereof is removed by a fluid flow that defines a thermal boundary layer, and wherein the plurality of microelectromechanical oscillatory devices are configured to oscillate to disrupt the thermal boundary layer.

72. A method according to claim 67 wherein the face is contained in an ambient fluid and wherein the plurality of microelectromechanical oscillatory devices are configured to oscillate to sweep the ambient fluid in a direction that is parallel to the face.

73. A method of cooling a microelectronic substrate that includes a face and that generates heat during operation thereof that is removed by a fluid flow that defines a thermal boundary layer adjacent the face, the method comprising:
disrupting the thermal boundary layer by movement of at least one electromechanical device.

74. A method according to claim 73 wherein the at least one electromechanical device comprises at least one microelectromechanical device.
